(19) United States
(12) Patent Application Publication
(10) Pub. No.: US 2018/0123211 A1
(43) Pub. Date: May 3, 2018

(54) RADIO FREQUENCY LOW-LOSS POWER DIVIDER/COMBINER AND POWER AMPLIFIER INCLUDING THE SAME

(71) Applicant: Electronics and Telecommunications Research Institute, Daejeon (KR)

(72) Inventors: Dong Pil CHANG, Daejeon (KR); Hongyeol LEE, Cheongju-si (KR); Changsoo KWAK, Daejeon (KR); Dong Hwan SHIN, Daejeon (KR); In Bok YOM, Daejeon (KR); Jin Cheol JEONG, Daejeon (KR)

(73) Assignee: Electronics and Telecommunications Research Instit ute, Daejeon (KR)

(21) Appl. No.: 15/584,662

(22) Filed: May 2, 2017

(30) Foreign Application Priority Data
Nov. 1, 2016 (KR) 10-2016-0144285

(51) Int. Cl. H01P 5/12; H01P 5/16; H03F 3/21

(52) U.S. Cl. CPC H01P 5/12; H01P 3/081; H03F 3/211; H01P 5/16

(57) ABSTRACT

Disclosed is a radio frequency low-loss power divider/combiner and power amplifier including the same, the power divider/combiner including a waveguide and a converter configured to convert an input signal received from an input signal terminal into a plurality of output signals and output the plurality of output signals to a plurality of output signal terminals corresponding to the plurality of output signals through the waveguide, wherein the waveguide includes the converter.

### CROSS-REFERENCE TO RELATED APPLICATION(S)

This application claims the priority benefit of Korean Patent Application No. 10-2016-0144285 filed on Nov. 1, 2016, in the Korean Intellectual Property Office, the disclosure of which is incorporated herein by reference for all purposes.

### BACKGROUND

### 1. Field

One or more example embodiments relate to a radio frequency low-loss power divider/combiner and a power amplifier including the radio frequency low-loss power divider/combiner.

### 2. Description of Related Art

Recently, for development of a solid-state power amplifier using a semiconductor amplifier, technologies related to a planar power divider/combiner, a waveguide-based power divider/combiner, or a spatial power divider/combiner are used to combine a plurality of amplifier modules in parallel. Each of the technologies may be applied to a different field based on, for example, an efficiency characteristic corresponding to a loss characteristic and a possibility of miniaturization.

The planar power divider/combiner may be implemented in a small size and configured to combine amplifier sub-modules in parallel in a planar structure. However, when operating frequency or a size of sub-module increases, a transmission loss of the planar power divider/combiner may also increase and thus, an overall efficiency of an amplifier may be drastically reduced.

The waveguide-based power divider/combiner may occupy relatively large area and space. Also, an interface of an amplifier sub-module of input and output coaxial transmission lines or a planar circuit amplifier may need to be changed to a waveguide.

### SUMMARY

An aspect provides a power divider/combiner that combines a waveguide and a coaxial transmission line to be used for a power distribution and combination of a radio frequency signal, thereby achieving a low-loss characteristic.

Another aspect also provides technology for providing a power divider/combiner in a small size.

According to an aspect, there is provided a power divider/combiner including a waveguide and a converter configured to convert an input signal received from an input signal terminal into a plurality of output signals, and output the plurality of output signals to a plurality of output signal terminals respectively corresponding to the plurality of output signals through the waveguide, wherein the waveguide includes the converter.

The power divider/combiner may further include a coaxial transmission line connected to the input signal terminal to transmit the input signal to the converter.

The converter may include a first converter configured to convert the input signal into a first output signal among the plurality of output signals and output the first output signal; and a second converter configured to convert the input signal into a second output signal among the plurality of output signals and output the second output signal.

The first output signal and the second output signal may have the same attribute.

The same attribute may include at least one of a phase and an amplitude.

The input signal terminal may be an input coaxial transmission line, and the plurality of output signal terminals may each be an output coaxial transmission line.

According to another aspect, there is also provided a power divider/combiner including a waveguide, a first converter configured to convert an input signal received from an input signal terminal into a plurality of first output signals, and output the plurality of first output signals to a plurality of first output signal terminals respectively corresponding to the plurality of first output signals through the waveguide, and a second converter configured to convert the input signal into a plurality of second output signals, and output the plurality of second output signals to a plurality of second output signal terminals respectively corresponding to the plurality of second output signals through the waveguide, wherein the waveguide includes the first converter and the second converter.

The power divider/combiner may further include a coaxial transmission line connected to the input signal terminal to transmit the input signal to the first converter and the second converter.

The plurality of first output signals and the plurality of second signals may have the same attribute.

The same attribute may include at least one of a phase and an amplitude.

The input signal terminal may be an input coaxial transmission line, and the plurality of first output signal terminals and the plurality of second signal terminals may be output coaxial transmission lines.

According to still another aspect, there is also provided a power amplifier including a power divider/combiner and a plurality of amplifier sub-modules configured to connect to a plurality of output terminals of the power divider/combiner, respectively, wherein the power divider/combiner includes a waveguide and a converter configured to convert an input signal received from an input signal terminal into a plurality of output signals and output the plurality of output signals to a plurality of output signal terminals respectively corresponding to the plurality of output signals through the waveguide, and the waveguide includes the converter.

The power divider/combiner may further include a coaxial transmission line connected to the input signal terminal to transmit the input signal to the converter.

The converter may include a first converter configured to convert the input signal into a first output signal among the plurality of output signals and output the first output signal and a second converter configured to convert the input signal into a second output signal among the plurality of output signals and output the second output signal.

The first output signal and the second output signal may have the same attribute.

The same attribute may include at least one of a phase and an amplitude.

The input signal terminal may be an input coaxial transmission line, and the plurality of output signal terminals may each be an output coaxial transmission line.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1A illustrates an example of a power divider/combiner implemented in a planar form;

FIG. 1B illustrates an example of a simulation result about a transmission loss of the power divider/combiner of FIG. 1A;

FIG. 2A illustrates an example of a power divider/combiner including a waveguide;

FIG. 2B illustrates an example of a simulation result about a transmission loss of the power divider/combiner of FIG. 2A;

FIG. 3 illustrates an example of a power divider/combiner having a coaxial transmission line-to-waveguide converter connected to an input;

FIG. 4A illustrates an example of a power divider/combiner;

FIG. 4B illustrates a simulation result about a transmission loss of the power divider/combiner of FIG. 4A;

FIG. 5A illustrates another example of a power divider/combiner;

FIG. 5B illustrates an example of a simulation result about a transmission loss of the power divider/combiner of FIG. 5A;

FIG. 6 illustrates an example of a power amplifier using the power divider/combiner of FIG. 5A; and

FIG. 7 illustrates still another example of a power divider/combiner.

### DETAILED DESCRIPTION

Detailed example embodiments of the inventive concepts are disclosed herein. However, specific structural and functional details disclosed herein are merely representative for purposes of describing example embodiments of the inventive concepts. Example embodiments of the inventive concepts may, however, be embodied in many alternate forms and should not be construed as limited to only the embodiments set forth herein.

Accordingly, while example embodiments of the inventive concepts are capable of various modifications and alternative forms, embodiments thereof are shown by way of example in the drawings and will herein be described in detail. It should be understood, however, that there is no intent to limit example embodiments of the inventive concepts to the particular forms disclosed, but to the contrary, example embodiments of the inventive concepts are to cover all modifications, equivalents, and alternatives falling within the scope of example embodiments of the inventive concepts.

Terms such as first, second, A, B, (a), (b), and the like may be used herein to describe components. Each of these terminologies is not used to define an essence, order or sequence of a corresponding component but used merely to distinguish the corresponding component from other component(s). For example, a first component may be referred to a second component, and similarly the second component may also be referred to as the first component.

It should be noted that if it is described in the specification that one component is “connected,” “coupled,” or “joined” to another component, a third component may be “connected,” “coupled,” and “joined” between the first and second components, although the first component may be directly connected, coupled or joined to the second component. In addition, it should be noted that if it is described in the specification that one component is “directly connected” or “directly joined” to another component, a third component may not be present therebetween. Likewise, expressions, for example, “between” and “immediately between” and “adjacent to” and “immediately adjacent to” may also be construed as described in the foregoing.

The terminology used herein is for the purpose of describing particular embodiments only and is not intended to be limiting. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms, including technical and scientific terms, used herein have the same meaning as commonly understood by one of ordinary skill in the art to which this disclosure pertains. Terms, such as those defined in commonly used dictionaries, are to be interpreted as having a meaning that is consistent with their meaning in the context of the relevant art, and are not to be interpreted in an idealized or overly formal sense unless expressly so defined herein.

Hereinafter, example embodiments will be described in detail with reference to the accompanying drawings, wherein like reference numerals refer to like elements throughout. However, it should be understood that there is no intent to limit this disclosure to the particular example embodiments disclosed.

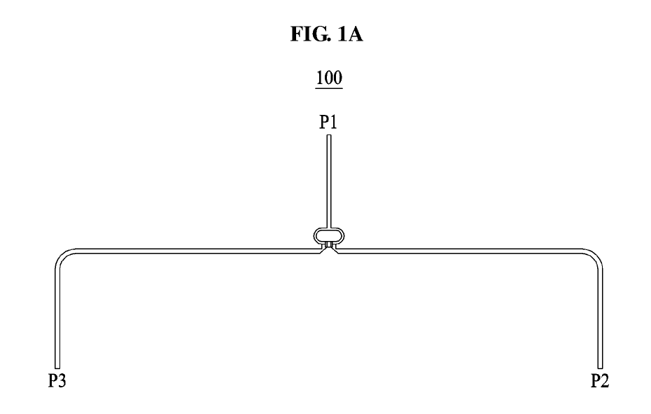

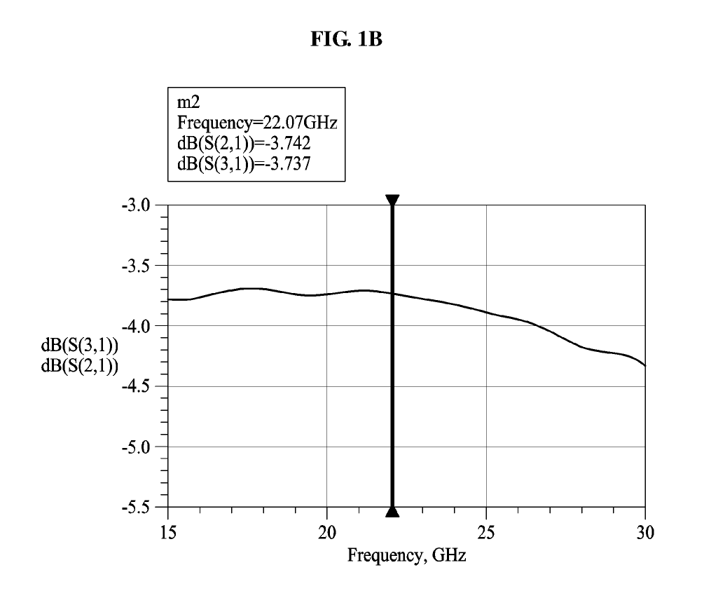

FIG. 1A illustrates an example of a power divider/combiner implemented in a planar form, and FIG. 1B illustrates an example of a simulation result about a transmission loss of the power divider/combiner of FIG. 1A.

Referring to FIGS. 1A and 1B, a power divider/combiner 100 may be a planar power divider/combiner. The power divider/combiner 100 may include an input signal terminal P1 and a plurality of output signal terminals P2 and P3.

The power divider/combiner 100 may have a 1:2 structure in which a single input signal output is divided into two output signal terminals. For example, the power divider/combiner 100 may have a 1:2 structure in which the input signal terminal P1 is divided into the output signal terminals P2 and P3 at a distance of about 30 millimeters (mm). In this example, when the power divider/combiner 100 is fabricated as an alumina substrate corresponding to an microwave (or radio frequency) low-loss substrate in a 22 gigahertz (GHz) frequency band, a transmission loss of about 0.7 decibels (dB) or more may occur.

A simulation result about a transmission loss of the power divider/combiner 100 may be as illustrated in FIG. 1B. A result about a transmission loss measured by manufacturing the power divider/combiner 100 as described above may exhibit a characteristic similar to that of the simulation result.

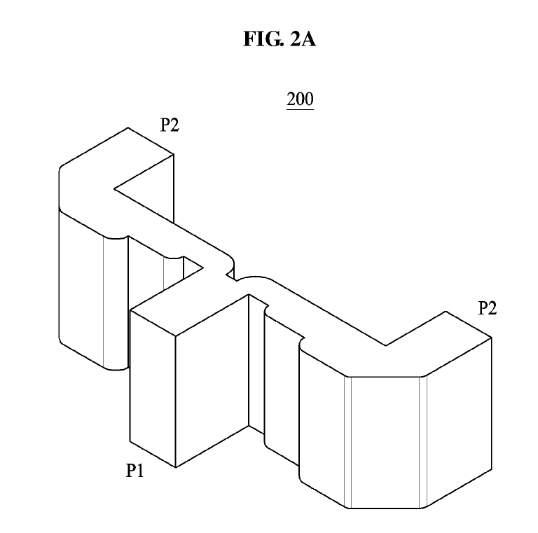

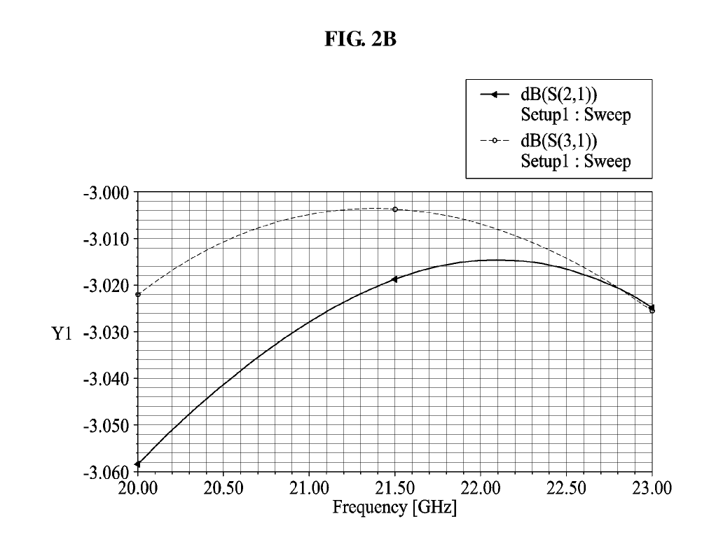

FIG. 2A illustrates an example of a power divider/combiner including a waveguide and FIG. 2B illustrates an example of a simulation result about a transmission loss of the power divider/combiner of FIG. 2A.

Referring to FIGS. 2A and 2B, a power divider/combiner 200 may be a waveguide-based power divider/combiner, for example, a power divider/combiner in a waveguide structure. The power divider/combiner 200 may include a waveguide 210, an input signal terminal P1, and a plurality of output signal terminals P2 and P3.

The power divider/combiner 200 may have a 1:2 structure in which a single input signal output is divided into two output signal terminals. For example, the power divider/combiner 200 may be configured to operate in a 22 GHz frequency band based on the waveguide 210, and may have a 1:2 structure in which the input signal terminal P1 is divided into the output signal terminals P2 and P3 at a distance of 30 mm.

A simulation result about a transmission loss of the power divider/combiner 200 may be as illustrated in FIG. 2B. A result about a transmission loss measured by manufacturing the power divider/combiner 200 may also exhibit a characteristic similar to that of the simulation result.

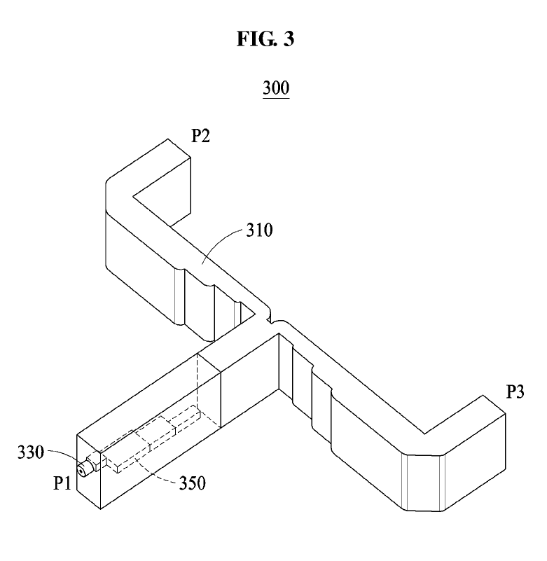

FIG. 3 illustrates an example of a power divider/combiner having a coaxial transmission line-to-waveguide converter connected to an input.

Referring to FIG. 3, a power divider/combiner 300 may be a waveguide-based power divider/combiner, for example, a power divider/combiner in a waveguide structure. The power divider/combiner 300 may include a waveguide 310, an input signal terminal P1, and a plurality of output signal terminals P2 and P3.

The power divider/combiner 300 may further include a coaxial transmission line 330 and a coaxial transmission line-to-waveguide converter 350. The coaxial transmission line 330 and the coaxial transmission line-to-waveguide converter 350 may connect the input signal terminal P1 and the waveguide 310.

The coaxial transmission line-to-waveguide converter 350 may be an interface device connected to an amplifier sub-module and implemented as a planar substrate or a coaxial connector when the waveguide-based power divider/combiner is used in, for example, a power amplifier.

In comparison to the simulation results of FIGS. 1B and 2B, the transmission loss of the waveguide-based power divider/combiner may be about 0.7 dB less than the transmission loss of the planar power divider/combiner. In this example, it is indicated that the waveguide-based power divider/combiner has little transmission loss.

The planar power divider/combiner of FIG. 1A may be readily connected to amplifier sub-modules implemented as a planar substrate in general, and implemented with a relatively small area. Meanwhile, as discussed above, because the planar power divider/combiner has a relatively high transmission loss, an efficiency may decrease after the planar power divider/combiner is connected to the plurality of amplifier sub-modules in parallel in order to be used in, for example, a power amplifier.

The waveguide-based power divider/combiner of FIG. 2A may require a converting device or a converter for an interface terminal, as described with reference to the power divider/combiner 300 of FIG. 3, in order to be connected to an amplifier sub-module implemented in a form of a planar substrate or a coaxial connector when the waveguide-based power divider/combiner is used in a power amplifier. For this reason, a size of the waveguide-based power divider/combiner, that is, the power divider/combiner 200 or 300 may increase.

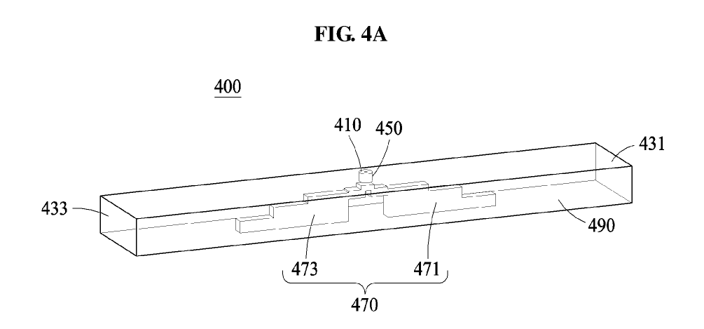

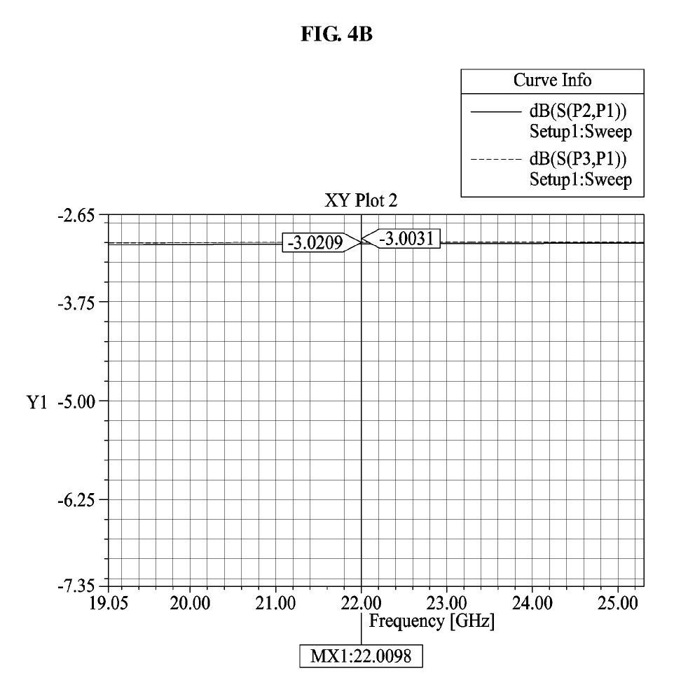

FIG. 4A illustrates an example of a power divider/combiner and FIG. 4B illustrates a simulation result about a transmission loss of the power divider/combiner of FIG. 4A.

Referring to FIGS. 4A and 4B, a power divider/combiner 400 may include an input signal terminal 410, a plurality of output signal terminals 431 and 433, a coaxial transmission line 450, a converter 470, and a waveguide 490. The power divider/combiner 400 may be implemented in a high-output amplifier operating in radio frequency and/or microwave frequency band.

The power divider/combiner 400 may have a 1:2 structure in which the input signal terminal 410 is divided into the plurality of output signal terminals 431 and 433.

The input signal terminal 410 may be connected to the coaxial transmission line 450. The input signal terminal 410 may receive an input signal. In this example, the input signal may be transmitted to the converter 470 through the coaxial transmission line 450. The input signal terminal 410 may be a signal combining terminal.

The converter 470 may convert the input signal transmitted to the coaxial transmission line 450 into a plurality of output signals and output the plurality output signals to the plurality of output signal terminals 431 and 433 corresponding to the plurality output signals. The converter 470 may be located or implemented in the waveguide 490 to change a signal path of the input signal from the coaxial transmission line 450 to the waveguide 490. That is, the waveguide 490 may include the converter 470.

The converter 470 may include a first converter 471 and a second converter 473. The first converter 471 and the second converter 473 may each be a coaxial transmission line-to-waveguide converter.

The first converter 471 and the second converter 473 may be connected to the coaxial transmission line 450. The first converter 471 may receive the input signal from the input signal terminal 410 through the coaxial transmission line 450. Also, the second converter 473 may receive the input signal from the input signal terminal 410 through the coaxial transmission line 450.

The first converter 471 may convert the input signal into a first output signal and output the first output signal to the output signal terminal 431 corresponding to the first output signal. The second converter 473 may convert the input signal into a second output signal and output the second output signal to the output signal terminal 433 corresponding to the second output signal. In this example, the output signal terminals 431 and 433 may be provided in a form of waveguide.

The first output signal and the second output signal may have the same attribute. For example, the first output signal and the second output signal may have at least one of the same phase and the same amplitude.

In response to the input signal being received through the coaxial transmission line 450, the converter 470 may generate the first output signal and the second output signal having the same phase and/or the same amplitude. The converter 470 may output the first output signal to the output signal terminal 431 and output the second output signal to the output signal terminal 433.

FIG. 4B illustrates a simulation result of a power divider/combiner that is designed to be suitable for a 22 GHz frequency band based on a structure of the power divider/combiner 400 of FIG. 4A. As illustrated in FIG. 4B, the power divider/combiner 400 may have an attribute similar to an attribute of the waveguide-based power divider/combiner 300 of FIG. 3. Also, as a measurement result obtained by manufacturing the power divider/combiner 400 as a sample, it is shown that the power divider/combiner 400 has an transmission loss less than about 0.1 dB. That is, the performance of the power divider/combiner 400 is shown to be very outstanding.

For power division and combination of a radio frequency and/or microwave signal, the power divider/combiner 400 may use a combination of the waveguide 490 and the coaxial transmission line 450, thereby realizing a low-loss characteristic.

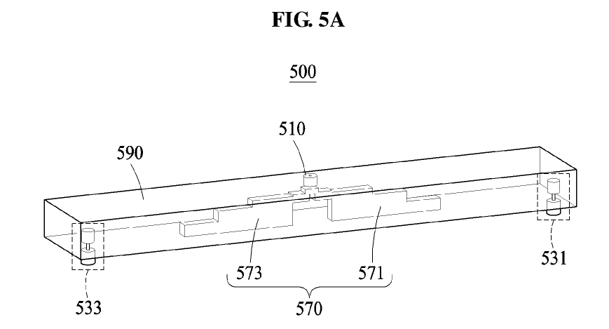

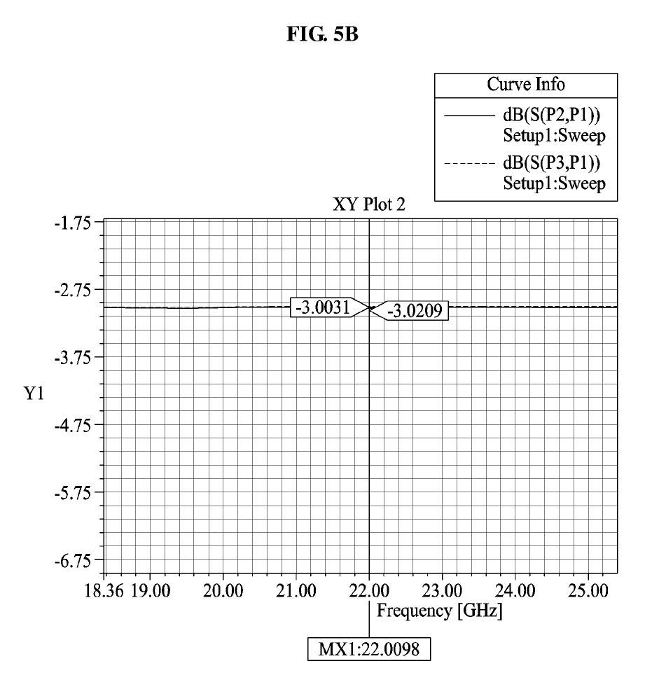

FIG. 5A illustrates another example of a power divider/combiner and FIG. 5B illustrates an example of a simulation result about a transmission loss of the power divider/combiner of FIG. 5A.

Referring to FIGS. 5A and 5B, a power divider/combiner 500 may include an input signal terminal 510, a plurality of output signal terminals 531 and 533, a converter 570, and a waveguide 590. The power divider/combiner 500 may be implemented in a high-output amplifier operating in radio frequency and/or microwave frequency band. The power divider/combiner 500 may have a 1:2 structure in which the single input signal terminal 510 is divided into the two output signal terminals 531 and 533. The input signal terminal 510 may be, for example, a signal combining terminal.

The input signal terminal 510 and the plurality of output signal terminals 531 and 533 may be a coaxial transmission line. Input and/or output (I/O) terminals, for example, the input signal terminal 510 and the output signal terminals 531 and 533 of the power divider/combiner 500 may be implemented as the coaxial transmission line. Thus, a parallel power combination between the power divider/combiner 500 and an amplifier sub-module having I/O terminals of a coaxial transmission line may be easily performed.

The converter 570 may convert an input signal input to an input coaxial transmission line, for example, the input signal terminal 510 into a plurality of output signals. Also, the converter may output the plurality of output signals to a plurality of output coaxial transmission lines, for example, the plurality of output signal terminals 531 and 533 corresponding to the plurality of output signals. The converter 570 may be located or implemented in the waveguide 580 to convert a signal path of the input signal from the input coaxial transmission line to the waveguide 590. That is, the waveguide 590 may include the converter 570.

The converter 570 may include a first converter 571 and a second converter 573. The first converter 571 and the second converter 573 may be a coaxial transmission line-to-waveguide converter.

The first converter 571 and the second converter 573 may be connected to the input coaxial transmission line. The first converter 571 and the second converter 573 may receive the input signal from the input coaxial transmission line.

The first converter 571 may convert the input signal into a first output signal and output the first output signal to the output coaxial transmission line corresponding to the first output signal. The second converter 573 may convert the input signal into a second output signal and output the second output signal to the output coaxial transmission line corresponding to the second output signal.

The first output signal and the second output signal may have the same attribute. For example, the first output signal and the second output signal may have at least one of the same phase and the same amplitude.

In response to the input signal being received through the input coaxial transmission line 510, the converter 570 may generate the first output signal and the second output signal having the same phase and/or the same amplitude. The converter 570 may output the first output signal to the output coaxial transmission line and output the second output signal to the output coaxial transmission line.

FIG. 5B illustrates a simulation result of a power divider/combiner that is designed to be suitable for a 22 GHz band based on a structure of the power divider/combiner 500 of FIG. 5A. Similarly to the simulation result of FIG. 4B, the power divider/combiner 500 may have a transmission loss less than about 0.1 dB.

For power division and combination of a radio frequency signal, the power divider/combiner 500 may use a combination of the waveguide 590 and coaxial transmission lines, for example, the input coaxial transmission line 510 and the output coaxial transmission lines 531 and 533, thereby realizing a low-loss characteristic.

As illustrated in FIG. 5A, similarly or identically to FIG. 4A, since the converter 570 is located or implemented in the waveguide 590, the waveguide 590 may occupy a great portion in a total size of the power divider/combiner 500. Also, the power divider/combiner 500 may not require a bend to change a signal promotion direction to the waveguide 590 and thus, may be implemented in a relatively small size.

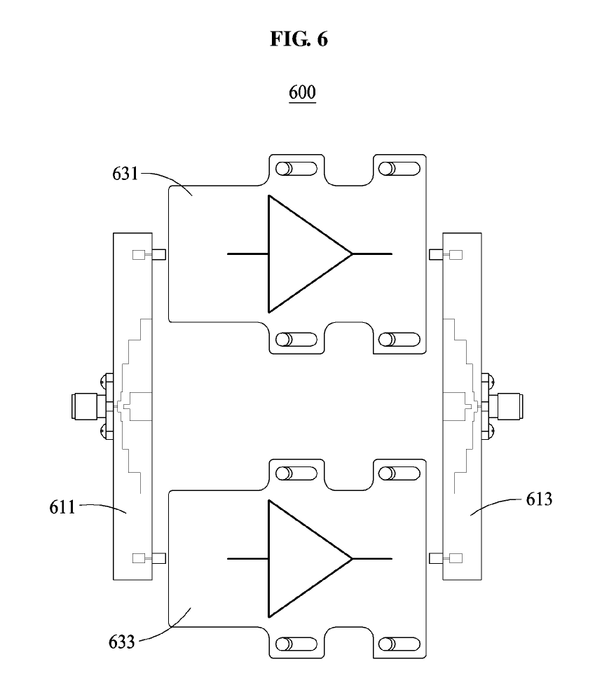

FIG. 6 illustrates an example of a power amplifier using the power divider/combiner of FIG. 5A.

Referring to FIG. 6, a power amplifier 600 may include a plurality of power dividers/combiners 611 and 613 and a plurality of amplifier sub-modules 631 and 633.

Configurations and operations of the plurality of power dividers/combiners 611 and 613 of FIG. 6 may be substantially the same as a configuration and an operation of the power divider/combiner 500 as described with reference to FIGS. 5A and 5B.

The plurality of amplifier sub-modules 631 and 633 may include an I/O coaxial transmission line or terminal. The plurality of power dividers/combiners 611 and 613 and the plurality of amplifier sub-modules 631 and 633 may be connected or combined in parallel to configure the power amplifier 600.

The power divider/combiner 613 corresponding to an output end of the power amplifier 600 may have a transmission loss less than or equal to 0.1 dB. Thus, an output power of the power amplifier 600 may be increased by about 2.9 dB when compared to a power outputtable by a single amplifier module.

As illustrated in FIG. 6, when combining high-output power amplifier sub-modules manufactured in a planar structure, that is, the amplifier sub-modules 631 and 633 in parallel, the power divider/combiner 611 and 613 may be implemented to have the low-loss characteristic similar or identical to that of the waveguide-based power/combiner and minimize a hardware area, thereby minimizing a decrease in output power or a decrease in efficiency of the power amplifier 600 due to the transmission loss.

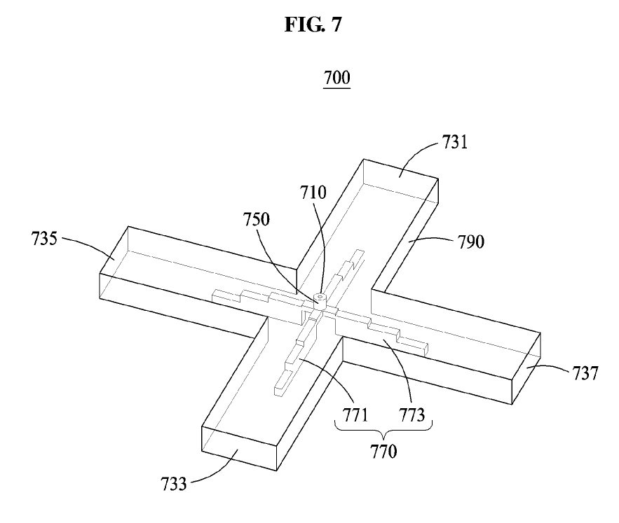

FIG. 7 illustrates an example of a power divider/combiner.

Referring to FIG. 7, a power divider/combiner 700 may include an input signal terminal 710, a plurality of output signal terminals 731, 733, 735, and 737, a coaxial transmission line 750, a converter 770, and a waveguide 790.

The power divider/combiner 700 may have a 1:4 structure in which the single input signal terminal 710 is divided into the four output signal terminals 731, 733, 735, and 737.

The input signal terminal 710 may be connected to the coaxial transmission line 750. The input signal terminal 710 may receive an input signal. In this example, the input signal may be transmitted to the converter 770 through the coaxial transmission line 750. The input signal terminal 710 may be, for example, a signal combining terminal.

The converter 770 may include a first converter 771 and a second converter 773. Configurations and operations of the first converter 771 and the second converter 773 may be substantially the same as a configuration and an operation of the converter 470 of FIG. 4A. That is, the waveguide 790 may include the converter 770.

The first converter 771 and the second converter 773 may be connected to the coaxial transmission line 750. The first converter 771 may receive the input signal from the input signal terminal 710 through the coaxial transmission line 750. Also, the second converter 773 may receive the input signal from the input signal terminal 710 through the coaxial transmission line 750.

The first converter 771 may convert the input signal into first output signals and output the first output signals to the output signal terminals 731 and 733 corresponding to the first output signals. The second converter 773 may convert the input signal into second output signals and output the second output signals to the output signal terminals 735 and 737 corresponding to the second output signals.

The first output signals and the second output signals may have the same attribute. For example, the first output signals and the second output signals may be the same in phase and amplitude.

The converter 770 may be included in the waveguide 790, and generate a plurality of output signals having the same phase and size in response to the input signal received through the coaxial transmission line 750. Also, the converter 770 may output the plurality of output signals to the plurality of output signal terminals 731, 733, 735, and 737 corresponding to the plurality of output signals.

Although FIG. 7 illustrates the power divider/combiner 700 having the 1:4 structure based on the structure of the power divider/combiner 400 of FIG. 4A, a structure of the power divider/combiner 700 is not limited thereto. The structure of the power divider/combiner 500 of FIG. 5A may also be applied to the power divider/combiner 700.

The components described in the exemplary embodiments of the present invention may be achieved by hardware components including at least one DSP (Digital Signal Processor), a processor, a controller, an ASIC (Application Specific Integrated Circuit), a programmable logic element such as an FPGA (Field Programmable Gate Array), other electronic devices, and combinations thereof. At least some of the functions or the processes described in the exemplary embodiments of the present invention may be achieved by software, and the software may be recorded on a recording medium. The components, the functions, and the processes described in the exemplary embodiments of the present invention may be achieved by a combination of hardware and software.

The processing device described herein may be implemented using hardware components, software components, and/or a combination thereof. For example, the processing device and the component described herein may be implemented using one or more general-purpose or special purpose computers, such as, for example, a processor, a controller and an arithmetic logic unit (ALU), a digital signal processor, a microcomputer, a field programmable gate array (FPGA), a programmable logic unit (PLU), a microprocessor, or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will be appreciated that a processing device may include multiple processing elements and/or multiple types of processing elements. For example, a processing device may include multiple processors or a processor and a controller. In addition, different processing configurations are possible, such as parallel processors.

The methods according to the above-described example embodiments may be recorded in non-transitory computer-readable media including program instructions to implement various operations of the above-described example embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher level code that may be executed by the computer using an interpreter. The above-described devices may be configured to act as one or more software modules in order to perform the operations of the above-described example embodiments, or vice versa.

A number of example embodiments have been described above. Nevertheless, it should be understood that various modifications may be made to these example embodiments. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A power divider/combiner comprising:
a waveguide; and
a converter configured to convert an input signal received from an input signal terminal into a plurality of output signals, and output the plurality of output signals to a plurality of output signal terminals respectively corresponding to the plurality of output signals through the waveguide,
wherein the waveguide includes the converter.

2. The power divider/combiner of claim 1, further comprising:
a coaxial transmission line connected to the input signal terminal to transmit the input signal to the converter.

3. The power divider/combiner of claim 1, wherein the converter includes:
a first converter configured to convert the input signal into a first output signal among the plurality of output signals and output the first output signal; and
a second converter configured to convert the input signal into a second output signal among the plurality of output signals and output the second output signal.

4. The power divider/combiner of claim 3, wherein the first output signal and the second output signal have the same attribute.

5. The power divider/combiner of claim 4, wherein the same attribute includes at least one of a phase and an amplitude.

6. The power divider/combiner of claim 1, wherein the input signal terminal is an input coaxial transmission line, and
the plurality of output signal terminals are each an output coaxial transmission line.

7. A power divider/combiner comprising:
a waveguide;
a first converter configured to convert an input signal received from an input signal terminal into a plurality of first output signals, and output the plurality of first output signals to a plurality of first output signal terminals respectively corresponding to the plurality of first output signals through the waveguide; and
a second converter configured to convert the input signal into a plurality of second output signals, and output the plurality of second output signals to a plurality of second output signal terminals respectively corresponding to the plurality of second output signals through the waveguide,
wherein the waveguide includes the first converter and the second converter.

8. The power divider/combiner of claim 7, further comprising:
a coaxial transmission line connected to the input signal terminal to transmit the input signal to the first converter and the second converter.

9. The power divider/combiner of claim 7, wherein the plurality of first output signals and the plurality of second signals have the same attribute.

10. The power divider/combiner of claim 9, wherein the same attribute includes at least one of a phase and an amplitude.

11. The power divider/combiner of claim 7, wherein the input signal terminal is an input coaxial transmission line, and
the plurality of first output signal terminals and the plurality of second signal terminals are output coaxial transmission lines.

12. A power amplifier comprising:
a power divider/combiner; and
a plurality of amplifier sub-modules configured to connect to a plurality of output terminals of the power divider/combiner, respectively,
wherein the power divider/combiner includes:
a waveguide; and
a converter configured to convert an input signal received from an input signal terminal into a plurality of output signals and output the plurality of output signals to a plurality of output signal terminals respectively corresponding to the plurality of output signals through the waveguide, and
wherein the waveguide includes the converter.

13. The power amplifier of claim 12, wherein the power divider/combiner further includes a coaxial transmission line connected to the input signal terminal to transmit the input signal to the converter.

14. The power amplifier of claim 12, wherein the converter includes:
a first converter configured to convert the input signal into a first output signal among the plurality of output signals and output the first output signal; and
a second converter configured to convert the input signal into a second output signal among the plurality of output signals and output the second output signal.

15. The power amplifier of claim 14, wherein the first output signal and the second output signal have the same attribute.

16. The power amplifier of claim 15, wherein the same attribute includes at least one of a phase and amplitude.

17. The power amplifier of claim 12, wherein the input signal terminal is an input coaxial transmission line, and
the plurality of output signal terminals are each an output coaxial transmission line.
